(19) United States
(12) Patent Application Publication
(10) Pub. No.: US 2019/0326524 A1
(43) Pub. Date: Oct. 24, 2019

(54) ORGANIC METAL COMPLEX, PREPARATION METHOD AND APPLICATION THEREOF

(71) Applicants: Nanjing Tech University, Nanjing (CN); AAC Microtech (Changzhou) Co., Ltd., Changzhou (CN)

(72) Inventors: Xiaochun Hang, Shenzhen (CN); Lu Zhu, Shenzhen (CN); Kang Shen, Shenzhen (CN); Zhikuan Chen, Shenzhen (CN); Jiuzhou Liu, Shenzhen (CN); Shaohai Chen, Saratoga, CA (US)

(21) Appl. No.: 16/112,867

(22) Filed: Aug. 27, 2018

(30) Foreign Application Priority Data
Apr. 18, 2018 (CN) 201810350105.8

(51) Int. Cl. H01L 51/00; C07F 15/00; C09K 11/06

(52) U.S. Cl. CPC H01L 51/0085; C07F 15/0033; C09K 11/06; H01L 51/5016; C09K 2211/1029; C09K 2211/1044; C09K 2211/185

(57) ABSTRACT

The present invention belongs to the field of organic light emitting materials and discloses an organic metal complex, its preparation method and an application thereof. The metal complex provided by the present invention has a general formula structure as shown in a formula (I). In the present invention, a ligand containing a pyridine unit is introduced into the cyclometalated iridium (trivalent) of the organic metal complex. The obtained hetero complex of the iridium (trivalent) has a light emitting interval ranging from a near infrared region to a blue light region, and has the advantages of wide spectrum application range and low volume production cost, so as to obtain a stable and high-efficient phosphorescent material.

### CROSS-REFERENCE TO RELATED APPLICATIONS

This application claims the priority benefit of Chinese Patent Applications Ser. No. 201810350105.8 filed on Apr. 18, 2018, the entire content of which is incorporated herein by reference.

### FIELD OF THE PRESENT DISCLOSURE

The present invention belongs to the field of organic electroluminescence materials, more particularly, to an organic metal complex, its preparation method and application thereof.

### DESCRIPTION OF RELATED ART

An Organic Light Emitting Diode (OLED) refers to a light emitting phenomenon in which an organic small molecule, a metal organic complex molecule or a polymer molecule of a light emitting material converts electric energy directly into light energy under a forward bias electric field. Since the OLED has the advantages of fast response speed, low driving voltage, high light emitting efficiency and resolution, high contrast, wide viewing angle, and the ability of emitting light independently without the need for backlight sources, the OLED attracts wide attention from the academic and industrial communities. In addition, it can also be produced on cheap glass, metal or even flexible plastic, and thus it also has the advantages of low cost, simple production process, and extensive production. It has become a new generation of full color display and lighting technology, and has wide and huge application prospect in the field of full color display and planar solid-state lighting.

The light emitting material used in the early device is mainly the organic small-molecule fluorescent material which can only use molecules that are in singlet state after electro excitation. Spin statistics quantum indicates that the theoretical quantum efficiency is only 25%. There are 75% excited molecules in an excited triplet state, which can emit phosphorescence by radiative transition back to the normal state, while a common organic small-molecule compound could hardly emit the phosphorescence at room temperature. Until a phosphorescent electroluminescence phenomenon of molecule materials of metal organic complexes at room temperature is discovered, the strong spin-orbit coupling of heavy metal atoms can effectively promote an intersystem crossing (ISC) of the electrons from the singlet state to the triplet state, so that the OLED device can make full use of all singlet and triplet excitons produced by electrical excitation to make the theoretical quantum efficiency of the light emitting material reach 100%. At this point, the study of organic light emitting material enters a completely new era.

Cyclometalated iridium (III) complex phosphorescent materials are a class of phosphorescent metal organic complexes that have been studied in an earlier stage. Great progresses have been made through nearly 20 years of studies and development. Two structures including homoleptic complex and heteroleptic complex can be used according to the composition of the molecular structure of the phosphorescent material of the cyclometalated iridium (III) complex, wherein an ancillary ligand (such as acetylacetone) in a light emitting material of an iridium (III) ancillary complex generally does not affect the energy level structure and the light emitting efficiency of the iridium (III) coordinated with the light emitting ligand. Therefore, the light emitting processes of the homoleptic complex and the heteroleptic complex are both determined by the coordinating moiety of the light emitting ligand thereof and the iridium (III). A heteroleptic mode generally has a very high synthesis efficiency, which can reduce the costs of material production and purification. The red and green phosphorescent materials of the cyclometalated iridium (III) complex have been used in commercial display devices, but the stability and device performance still need to be continuously improved. It is of practical significance to develop the phosphorescent materials of the cyclometalated iridium (III) complex with a new structural system.

### SUMMARY

The present invention aims at providing an organic metal complex, its preparation method and application thereof.

The object of the present invention is achieved through the following technical solutions.

The embodiments of the present invention provide an organic metal complex, which comprises a structure as shown in a general formula (I):

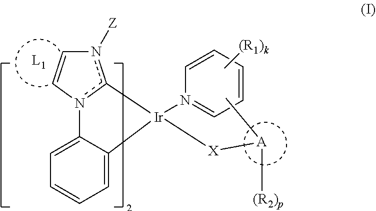

wherein,

each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to an adjacent aryl or substituent optionally;

a structure A is selected from substituted or unsubstituted C₁-C₆ alkylene, substituted or unsubstituted C₃-C₃₆ heteroaromatic ring, and substituted or unsubstituted C₆-C₃₆ aromatic ring; and the structure A is connected to a pyridine ring;

X represents a carbon atom, an oxygen atom or a nitrogen atom; and X is connected to the structure A or X is an atom in the structure A;

each of k and p is independently an integer of 1 to 4;

Z is a halogen, C₁-C₆ alkyl, or C₁-C₆ deuterated alkyl; and

L₁ is selected from substituted or unsubstituted C₃-C₃₆ heteroaromatic ring, and substituted or unsubstituted C₆-C₃₆ aromatic ring; and L₁ is condensed with an imidazole ring.

Preferably, in the organic metal complex provided by the embodiments of the present invention,

when X represents the carbon atom, the structure A is selected from substituted or unsubstituted C₃-C₃₆ heteroaromatic ring, and substituted or unsubstituted C₆-C₃₆ aromatic ring, and X is the atom in the structure A;

when X represents the nitrogen atom, the structure A is selected from substituted or unsubstituted C₃-C₃₆ heteroaromatic ring, and X is the atom in the structure A; and

when X represents the oxygen atom, the structure A is selected from substituted or unsubstituted C₁-C₆ alkylene, substituted or unsubstituted C₃-C₃₆ heteroaromatic ring, and substituted or unsubstituted C₆-C₃₆ aromatic ring, and X is connected to the structure A.

Preferably, the organic metal complex provided by the embodiments of the present invention comprises a structure as shown in a general formula (IA):

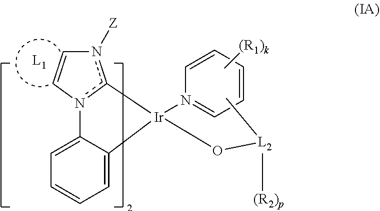

wherein,

each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to the adjacent aryl or substituent optionally;

each of k and p is independently an integer of 1 to 4;

L₂ is selected from substituted or unsubstituted C₁-C₆ alkylene, substituted or unsubstituted C₃-C₃₆ heteroaromatic ring, and substituted or unsubstituted C₆-C₃₆ aromatic ring; and L₂ is connected to the pyridine ring; and

Z is a halogen, C₁-C₆ alkyl, or C₁-C₆ deuterated alkyl.

Preferably, the organic metal complex provided by the embodiments of the present invention comprises a structure as shown in a general formula (IB):

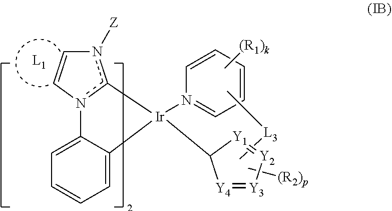

wherein,

each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to the adjacent aryl or substituent optionally;

each of k and p is independently an integer of 1 to 4;

each of Y₁, Y₂, Y₃ and Y₄ is independently selected from the nitrogen atom or the carbon atom;

L₃ is selected from a dummy atom, substituted or unsubstituted C₁-C₆ alkylene, substituted or unsubstituted C₃-C₃₆ heteroaromatic ring, and substituted or unsubstituted C₆-C₃₆ aromatic ring;

L₃ is connected to or condensed with the pyridine ring, and L₃ is connected to or condensed with a five-membered ring formed by Y₁, Y₂, Y₃ and Y₄ and an N atom; and

Z is a halogen, C₁-C₆ alkyl, or C₁-C₆ deuterated alkyl.

Preferably, in the general formula structure of the organic metal complex provided by the embodiments of the present invention, a right ligand

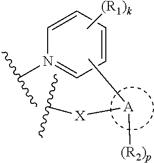

is selected from one of the following structures:

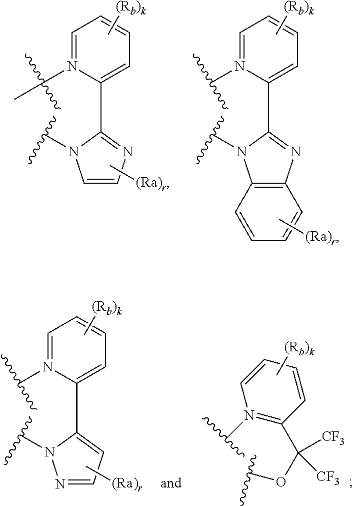

wherein,

each of Ra and Rb is independently selected from hydrogen, deuterium, substituted or unsubstituted C₁-C₆ alkyl, substituted or unsubstituted C₁-C₆ deuterated alkyl, substituted or unsubstituted C₆-C₃₆ aryl, and substituted or unsubstituted C₆-C₃₆ deuterated aryl, and each of Ra and Rb is independently connected to the adjacent aryl or substituent optionally; and

each of r and k is independently an integer of 1 to 4.

Preferably, in the general formula structure of the organic metal complex provided by the embodiments of the present invention, the right ligand

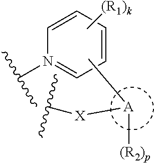

is selected from one of the following structures:

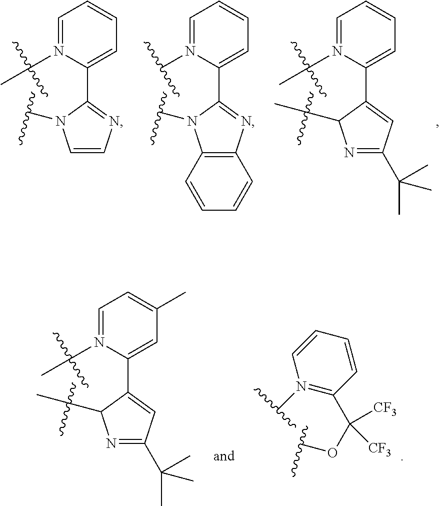

Preferably, in the general formula structure of the organic metal complex provided by the embodiments of the present invention, a left ligand

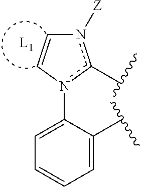

is selected from one of the following structures:

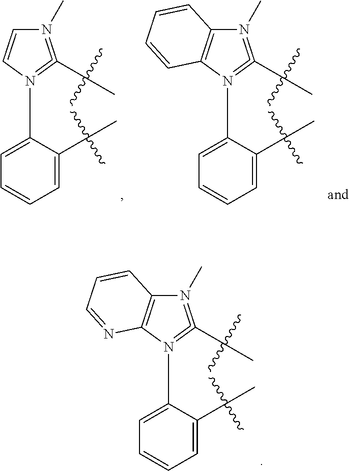

Preferably, the organic metal complex provided by the embodiments of the present invention has one of the structures as below:

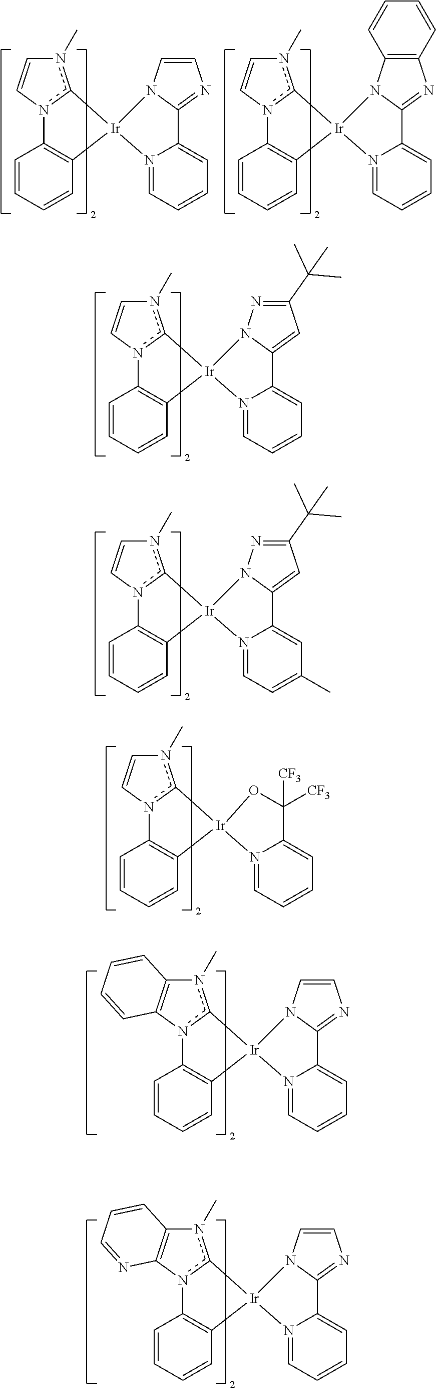

Preferably, a preparation method of the organic metal complex provided by the embodiments of the present invention comprises the following steps:

(1) obtaining a dimer by a precursor substance reacting with iridium chloride; and

(2) obtaining a compound as shown in the general formula (I) by the dimer reacting with a ligand compound;

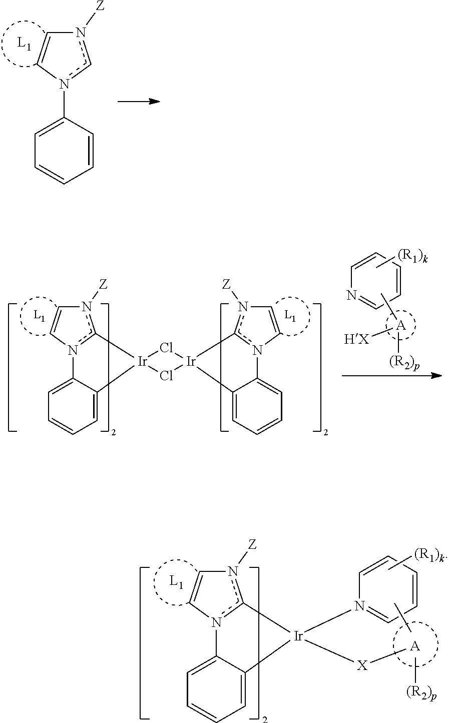

The embodiments of the present invention further provide an application of the organic metal complex above as a phosphorescent light emitting material in an organic light emitting device.

Further, the embodiments of the present invention further provide an organic electronic component, which comprises the organic metal complex above.

Preferably, the electronic component provided by the embodiments of the present invention is an organic light emitting diode, a compact fluorescent lamp, an organic photovoltaic cell, an organic field effect transistor or a light emitting electrochemical cell.

A three-coordinated electrically neutral cyclometalated iridium (III) complex phosphorescent material is synthesized in the embodiments of the present invention through a high-energy level (band gap energy) main ligand containing an N-heterocyclic carbene coordination ligand unit and an ancillary ligand containing a nitrogen pyridine unit. The obtained heteroleptic complex of the iridium (trivalent) may have a light emitting interval ranging from a near infrared region to a blue light region, and has the advantages of wide spectrum application range and low volume production cost.

The embodiments of the present invention further provide a design method and a molecular model of a phosphorescent material under the effect of orbital perturbation, which can reduce a singlet-triplet energy difference in excited state generally, and effectively improve the light emitting efficiency and stability. The embodiments of the present invention provide a synthesis method of such organic metal complex and its related material data, and compared with a control group of device application, the organic metal complex is applicable to an electroluminescent material serving as a phosphorescence light emitting device in display or lighting device.

### BRIEF DESCRIPTION OF THE DRAWINGS

FIG. 1 is an emission spectrum of Ir-1 in a dichloromethane solution and at room temperature;

FIG. 2 is an emission spectrum of Ir-2 in a dichloromethane solution and at room temperature;

FIG. 3 is an emission spectrum of Ir-3 in a dichloromethane solution and at room temperature;

FIG. 4 is an emission spectrum of Ir-4 in a dichloromethane solution and at room temperature;

FIG. 5 is an emission spectrum of Ir-5 in a dichloromethane solution and at room temperature;

FIG. 6 is an emission spectrum of Ir-7 in a dichloromethane solution and at room temperature;

FIG. 7 is an emission spectrum of Ir-9 in a dichloromethane solution and at room temperature;

FIG. 8 is a structure diagram of a light emitting device according to an embodiment of the present invention;

wherein: 10 refers to light emitting device; 11 refers to first electrode; 12 refers to hole transporting layer; 13 refers to light emitting layer; 14 refers to electronic transporting layer; and 15 refers to second electrode;

FIG. 9 is a distributed structure of LUMO (left)/HOMO (right) electron clouds of Ir(pmi)₂(ImPy);

FIG. 10 is a schematic diagram illustrating emission of a device of Ir-1;

FIG. 11 is an external quantum efficiency diagram of a device embodiment of Ir-1;

FIG. 12 is a nuclear magnetism spectrogram of Ir-2; and

FIG. 13 is a mass spectrogram of Ir-2.

### DETAILED DESCRIPTION OF THE EXEMPLARY EMBODIMENTS

To make the objectives, technical solutions, and advantages of the invention clearer, the following further describes the embodiments of the invention in detail with reference to the embodiments. However, those skilled in the art can understand that, in the embodiments of the invention, many technical details are proposed for readers to better understand the invention. However, even without these technical details and various changes and modifications based on the following embodiments, the technical solutions sought to be protected by claims of the invention can be realized.

Compounds

In some embodiments of the present invention, a design method and a molecular model of a phosphorescent material under the effect of orbital perturbation are provided, which can reduce a singlet-triplet energy difference in excited state generally, and effectively improve the light emitting efficiency and stability. The embodiments of the present invention provide a synthesis method of such organic metal complex and its related material data, and compared with a control group of device application instruction, the organic metal complex is applicable to an electroluminescent material serving as a phosphorescence light emitting device in display or lighting application.

In some embodiments of the present invention, an organic metal complex provided comprises a structure as shown in a general formula (I):

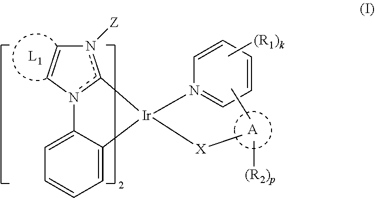

wherein,

each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to an adjacent aryl or substituent optionally;

a structure A is selected from substituted or unsubstituted C₁-C₆ alkylene, substituted or unsubstituted C₃-C₃₆ heteroaromatic ring, and substituted or unsubstituted C₆-C₃₆ aromatic ring; and the structure A is connected to a pyridine ring;

X represents a carbon atom, an oxygen atom or a nitrogen atom; and X is connected to the structure A or X is an atom in the structure A;

each of k and p is independently an integer of 1 to 4;

Z is a halogen, C₁-C₆ alkyl, or C₁-C₆ deuterated alkyl; and

L₁ is selected from substituted or unsubstituted C₃-C₃₆ heteroaromatic ring, and substituted or unsubstituted C₆-C₃₆ aromatic ring; and L₁ is condensed with an imidazole ring.

In the organic metal complex provided by some embodiments of the present invention,

when X represents the carbon atom, the structure A is selected from substituted or unsubstituted C₃-C₃₆ heteroaromatic ring, and substituted or unsubstituted C₆-C₃₆ aromatic ring, and X is the atom in the structure A;

when X represents the nitrogen atom, the structure A is selected from substituted or unsubstituted C₃-C₃₆ heteroaromatic ring, and X is the atom in the structure A; and

when X represents the oxygen atom, the structure A is selected from substituted or unsubstituted C₁-C₆ alkylene, substituted or unsubstituted C₃-C₃₆ heteroaromatic ring, and substituted or unsubstituted C₆-C₃₆ aromatic ring, and X is connected to the structure A.

In some embodiments of the present invention, the organic metal complex provided comprises a structure as shown in a general formula (IA):

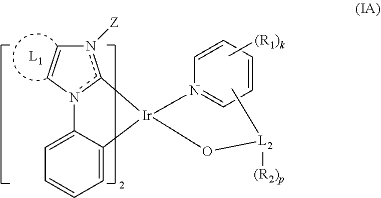

wherein,

each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to the adjacent aryl or substituent optionally;

each of k and p is independently an integer of 1 to 4;

L₂ is selected from substituted or unsubstituted C₁-C₆ alkylene, substituted or unsubstituted C₃-C₃₆ heteroaromatic ring, and substituted or unsubstituted C₆-C₃₆ aromatic ring; and L₂ is connected to the pyridine ring; and

Z is a halogen, C₁-C₆ alkyl, or C₁-C₆ deuterated alkyl.

In some embodiments of the present invention, the organic metal complex provided comprises a structure as shown in a general formula (IB):

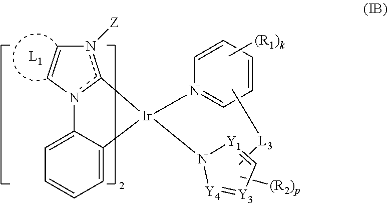

wherein,

each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to the adjacent aryl or substituent optionally;

each of k and p is independently an integer of 1 to 4;

each of Y₁, Y₂, Y₃ and Y₄ is independently selected from the nitrogen atom or the carbon atom;

L₃ is selected from a dummy atom, substituted or unsubstituted C₁-C₆ alkylene, substituted or unsubstituted C₃-C₃₆ heteroaromatic ring, and substituted or unsubstituted C₆-C₃₆ aromatic ring;

L₃ is connected to or condensed with the pyridine ring, and L₃ is connected to or condensed with a five-membered ring formed by Y₁, Y₂, Y₃, Y₄ and an N atom; and

Z is a halogen, C₁-C₆ alkyl, or C₁-C₆ deuterated alkyl.

In the general formula structure of the organic metal complex provided by some embodiments of the present invention, a right ligand

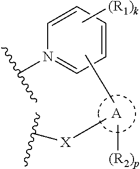

is selected from one of the following structures:

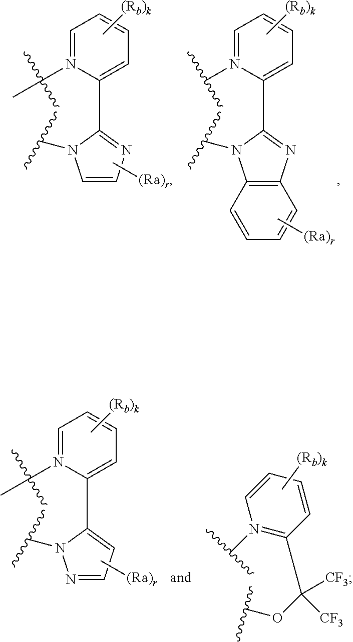

wherein,

each of Ra and R_{b} is independently selected from hydrogen, deuterium, substituted or unsubstituted C₁-C₆ alkyl, substituted or unsubstituted C₁-C₆ deuterated alkyl, substituted or unsubstituted C₆-C₃₆ aryl, and substituted or unsubstituted C₆-C₃₆ deuterated aryl, and each of Ra and Rb is independently connected to the adjacent aryl or substituent optionally; and

each of r and k is independently an integer of 1 to 4.

In the general formula structure of the organic metal complex provided by some embodiments of the present invention, a right ligand

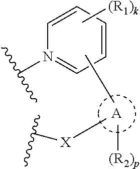

is selected from one of the following structures:

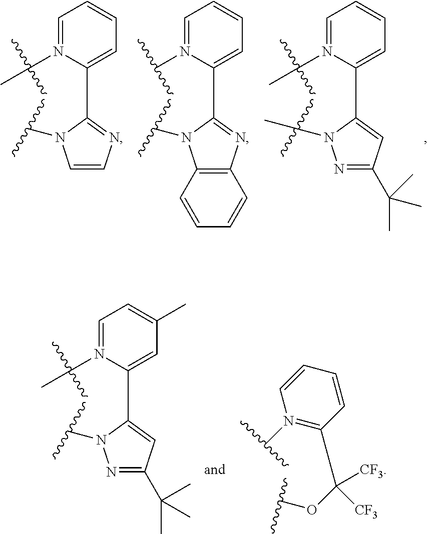

In the general formula structure of the organic metal complex provided by some embodiments of the present invention, a left ligand

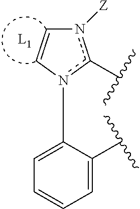

is selected from one of the following structures:

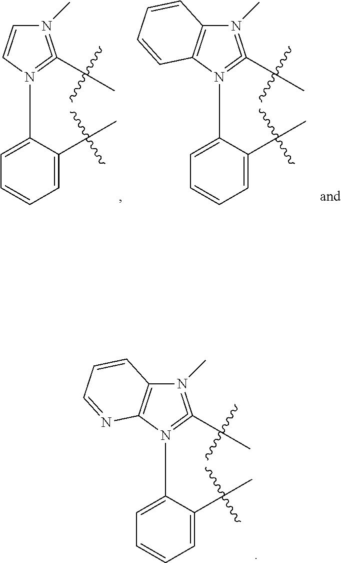

In some embodiments of the present invention, the organic metal complex provided has a structure selected from one of the following:

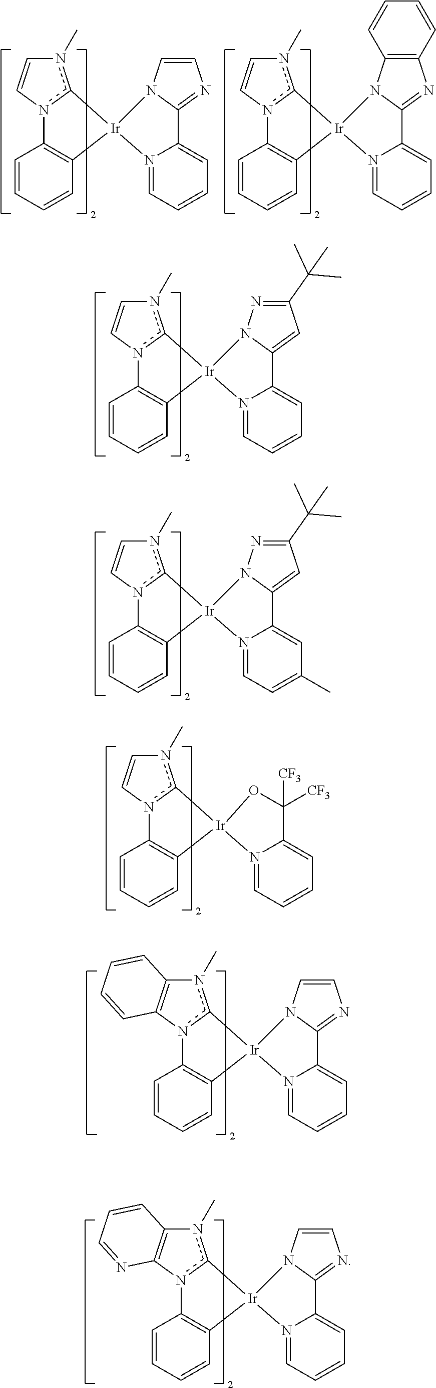

General Synthetic Route:

The embodiments of the present invention further provide a preparation method of the above-mentioned organic metal complex, which synthesizes the organic metal complex according to the following general synthetic route:

a dimer is obtained by a precursor substance L reacting with iridium chloride (IrCl₃); and

a compound as shown in the general formula I is obtained by the dimer reacting with a ligand compound;

a chemical reaction equation is shown as follows:

when the dimer is obtained by the precursor substance L reacting with the iridium chloride (IrCl₃), the dimer reacts with the ligand compound to obtain the compound as shown in the general formula I; and

the chemical reaction equation is shown as follows:

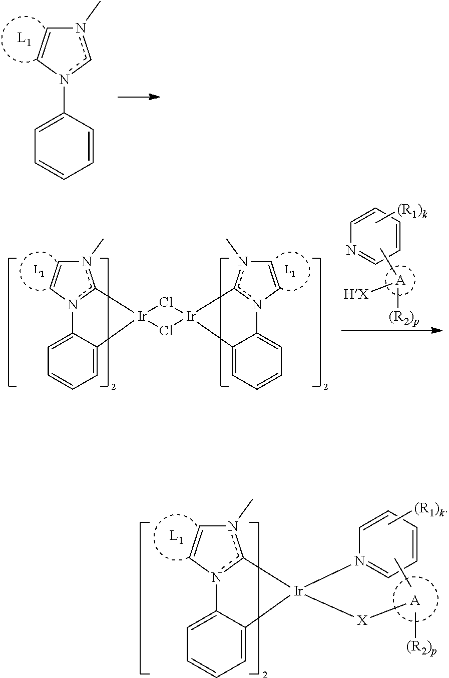

### SYNTHESIS EXAMPLES

### Synthesis Example 1: Ir-1 Synthesis and Structural Characterization

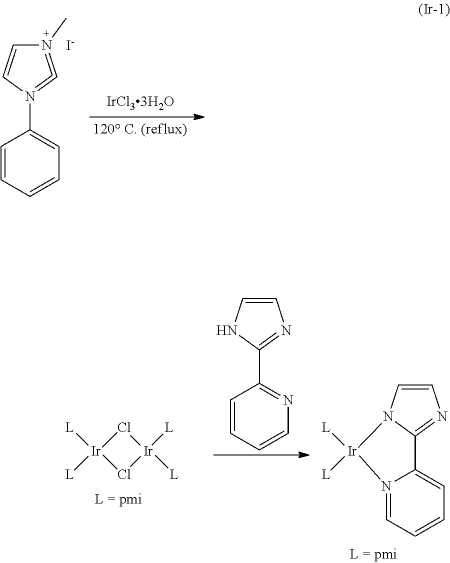

1-phenyl-3-methylimidazolium iodide, ethylene glycol monomethylether, silver oxide, and IrCl₃.3H₂O were added into a round-bottom flask, and a resulting solution was deflated in nitrogen atmosphere for three times, and then was refluxed in dark for 12 hours. After the reaction was completed, the temperature was returned to room temperature, the solvent was removed by filtration, a filter cake was eluted by dichloromethane, the eluent was concentrated to remove the solvent, and a resulting dimer solid was washed by methanol and dried in air.

Dimer (25 mg, 0.02 mmol, 1.0 eq), ligand (29 mg, 0.2 mmol, 10.0 eq), Na₂CO₃ (21 mg, 0.2 mmol, 10.0 eq), and ethylene glycol monomethylether (3 mL) were added into a 60 mL sealed tube, and bubbled by N₂ for 5 minutes, then the temperature was raised to 120° C., the mixture was cooled and added with water after reaction for 14 hours, and extracted by dichloromethane (DCM) to separate a liquid, organic phases were dried, and a target point was separated by column chromatography in the case of DCM:MeOH=20:1, thus obtaining a light yellow solid (23 mg in 71% yield).

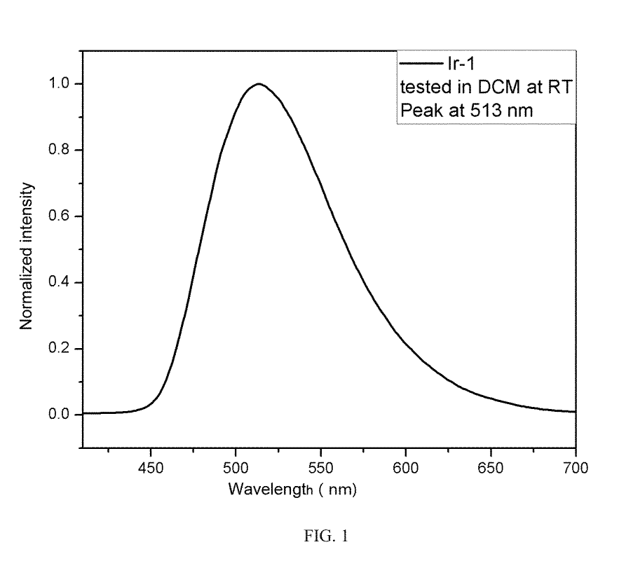

The emission spectrum in a dichloromethane solution and at room temperature was shown in FIG. 1, wherein a main emission peak was at 513 nm, and the Ir-1 was a green light material.

¹H-NMR (300 MHz, CDCl₃) δ: 7.89 (s, 1H), 7.53 (d, J=8.6 Hz, 1H), 7.43 (d, J=3.2 Hz, 2H), 7.36 (s, 1H), 7.17-7.01 (m, 5H), 6.98-6.81 (m, 4H), 6.68 (dq, J=15.1, 7.7 Hz, 2H), 6.53 (d, J=8.5 Hz, 2H), 3.11 (s, 3H), 3.00 (s, 3H).

ESI MS: 652.18, [M+H]⁺.

### Synthesis Example 2: Ir-2 Synthesis and Structural Characterization

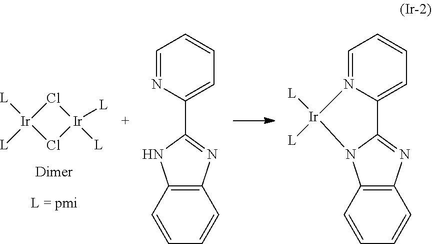

Dimer (25 mg, 0.02 mmol, 1.0 eq), ligand (38 mg, 0.20 mmol, 10.0 eq), Na₂CO₃ (21 mg, 0.20 mmol, 10.0 eq), and ethylene glycol monomethylether (3 mL) were added into a 60 mL sealed tube, and bubbled by N₂ for 5 minutes, then the temperature was raised to 120° C., the mixture was cooled and added with water after reaction for 14 hours, and extracted by dichloromethane (DCM) to separate a liquid, organic phases were dried, and a target point was separated by column chromatography in the case of DCM:MeOH=20:1, thus obtaining a light yellow solid (21 mg in 75% yield).

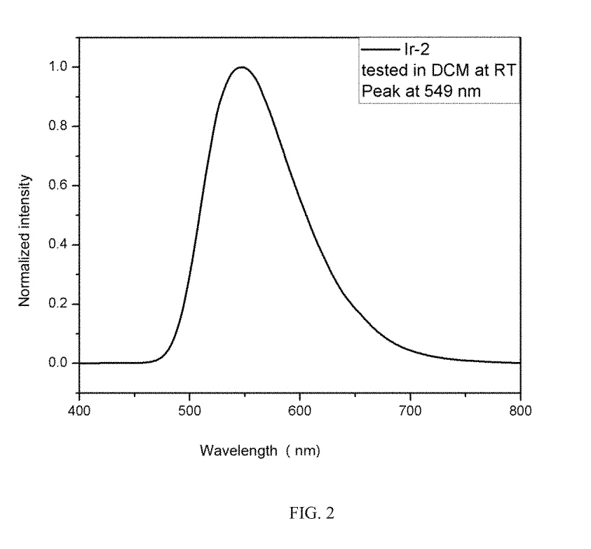

The emission spectrum in a dichloromethane solution and at room temperature was shown in FIG. 2, wherein a main emission peak was at 549 nm, and the Ir-2 was a green light material.

¹H-NMR (300 MHz, CDCl₃) δ: 9.17 (d, J=8.1 Hz, 1H), 8.03 (d, J=5.4 Hz, 1H), 7.89 (t, J=7.8 Hz, 1H), 7.81 (d, J=8.2 Hz, 1H), 7.43 (d, J=2.0 Hz, 1H), 7.36 (d, J=2.0 Hz, 1H), 7.18 (t, J=7.8 Hz, 1H), 7.15-7.06 (m, 3H), 6.95 (dtd, J=9.1, 7.5, 1.4 Hz, 2H), 6.86 (t, J=7.7 Hz, 1H), 6.80 (d, J=2.0 Hz, 1H), 6.78-6.66 (m, 3H), 6.54 (ddd, J=7.5, 4.5, 1.3 Hz, 2H), 6.18 (d, J=8.3 Hz, 1H), 2.97 (s, 3H), 2.90 (s, 3H).

ESI MS: 702.2, [M+H]+.

### Synthesis Example 3: Ir-3 Synthesis and Structural Characterization

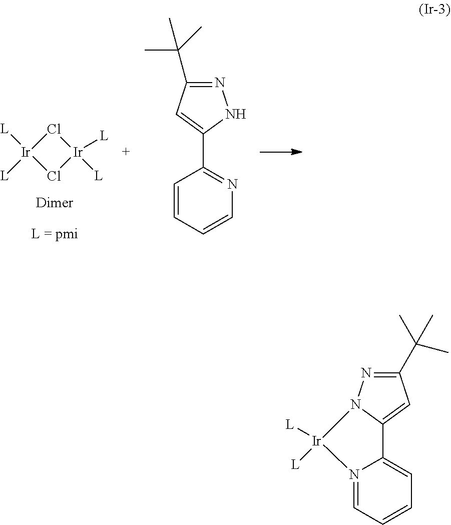

Dimer (25 mg, 0.02 mmol, 1.0 eq), ligand (40 mg, 0.20 mmol, 10.0 eq), Na₂CO₃ (21 mg, 0.20 mmol, 10.0 eq), and ethylene glycol monomethylether (3 mL) were added into a 60 mL sealed tube, and replaced by N₂ for three times, then the temperature was raised to 120° C., the mixture was cooled to room temperature after reaction for 20 hours, filtered, and eluted by 10 mL water, ethanol and petroleum ether respectively, a target point of solid was separated by column chromatography in the case of DCM:MeOH=20:1, thus obtaining a light yellow solid (18 mg in 64% yield).

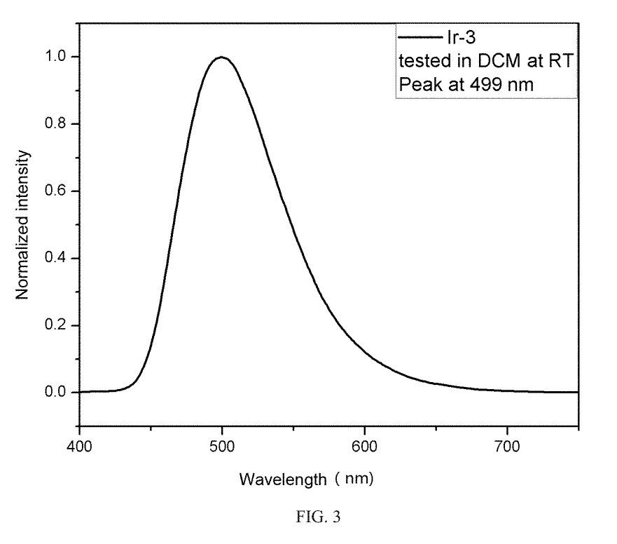

The emission spectrum in a dichloromethane solution and at room temperature was shown in FIG. 3, wherein a main emission peak was at 499 nm, and the Ir-3 was a blue-green light material.

ESI MS: 708.2, [M+H]⁺.

### Synthesis Example 4: Ir-4 Synthesis and Structural Characterization

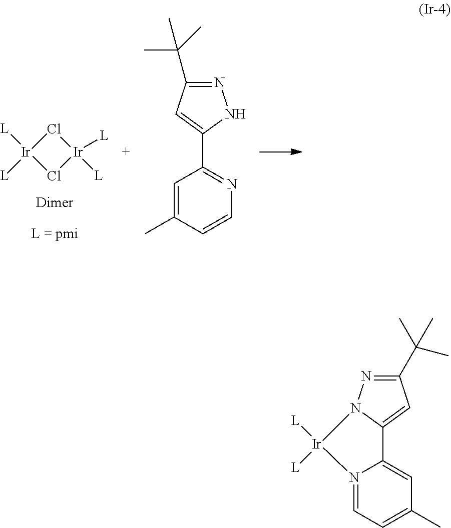

Dimer (25 mg, 0.02 mmol, 1.0 eq), ligand (41 mg, 0.20 mmol, 10.0 eq), Na₂CO₃ (21 mg, 0.20 mmol, 10.0 eq), and ethylene glycol monomethylether (3 mL) were added into a 60 mL sealed tube, and replaced by N₂ for three times, then the temperature was raised to 120° C., the mixture was cooled to room temperature after reaction for 20 hours, filtered, and eluted by 10 mL water, ethanol and petroleum ether respectively, a target point of solid was separated by column chromatography in the case of DCM:MeOH=20:1, thus obtaining a light green solid (20 mg in 69% yield).

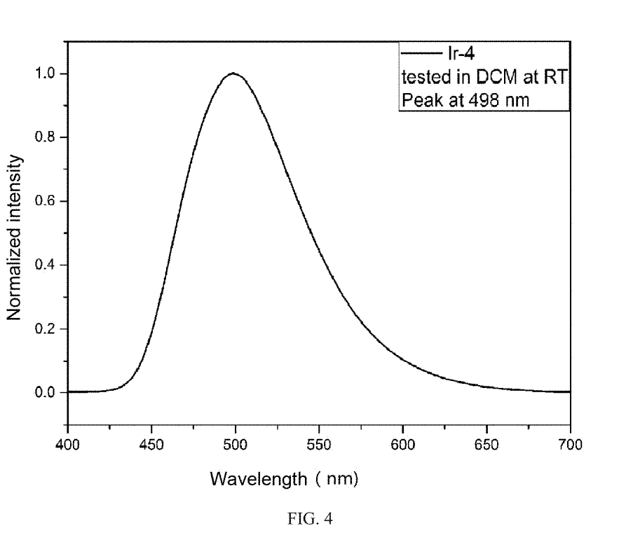

The emission spectrum in a dichloromethane solution and at room temperature was shown in FIG. 4, wherein a main emission peak was at 498 nm, and the Ir-4 was a blue-green light material.

¹H-NMR (300 MHz, CDCl₃) δ: 7.85-7.73 (m, 2H), 7.51 (t, J=1.6 Hz, 1H), 7.41 (t, J=1.6 Hz, 1H), 7.17 (d, J=7.8 Hz, 1H), 7.08 (d, J=7.7 Hz, 1H), 7.00 (dt, J=11.1, 1.6 Hz, 2H), 6.91 (t, J=7.5 Hz, 3H), 6.76 (d, J=1.2 Hz, 1H), 6.70 (dt, J=9.0, 7.4 Hz, 2H), 6.39 (dd, J=13.3, 7.4 Hz, 2H), 3.12 (s, J=1.3 Hz, 3H), 3.02 (s, J=1.3 Hz, 3H), 2.49 (s, 3H), 1.33 (s, J=1.3 Hz, 9H)

ESI MS: 722.3, [M+H]⁺.

### Synthesis Example 5: Ir-5 Synthesis and Structural Characterization

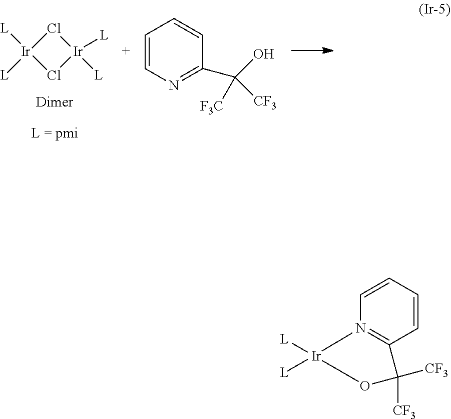

Dimer (25 mg, 0.02 mmol, 1.0 eq), a ligand (49 mg, 0.20 mmol, 10.0 eq), Na₂CO₃ (21 mg, 0.20 mmol, 10.0 eq), and ethylene glycol monomethylether (3 mL) were added into a 60 mL sealed tube, and replaced by N₂ for five times, then the temperature was raised to 90° C., the mixture was cooled to room temperature after reaction for 12 hours, filtered, and eluted by 10 mL water, ethanol and petroleum ether respectively, a target point of solid was separated by column chromatography in the case of PE:EA=5:1, thus obtaining a yellow solid (22 mg in 73% yield).

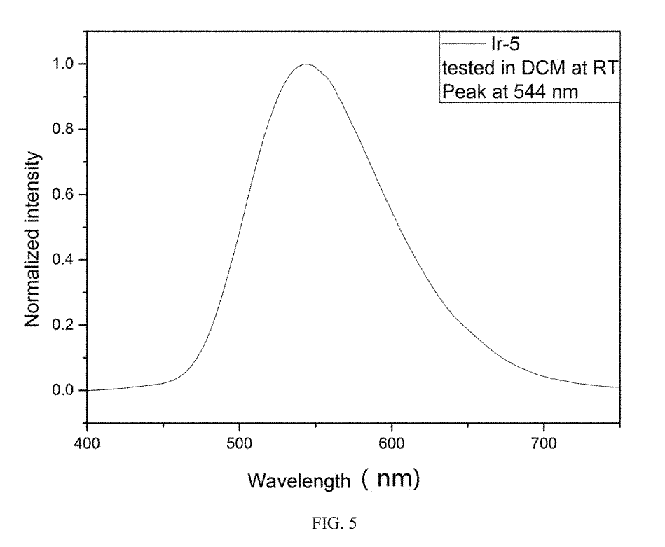

The emission spectrum in a dichloromethane solution and at room temperature was shown in FIG. 5, wherein a main emission peak was at 544 nm, and the Ir-5 was a green light material.

¹H-NMR (300 MHz, CDCl₃) δ: 7.94 (dt, J=5.5, 1.2 Hz, 1H), 7.75-7.66 (m, 2H), 7.46 (d, J=2.0 Hz, 1H), 7.40 (d, J=2.0 Hz, 1H), 7.16-6.95 (m, 4H), 6.90-6.72 (m, 3H), 6.58 (tt, J=7.4, 1.6 Hz, 2H), 6.29 (ddd, J=13.4, 7.5, 1.3 Hz, 2H), 4.16 (s, 3H), 2.91 (s, 3H).

ESI MS: 752, [M+H]⁺.

### Synthesis Example 7: Ir-7 Synthesis and Structural Characterization

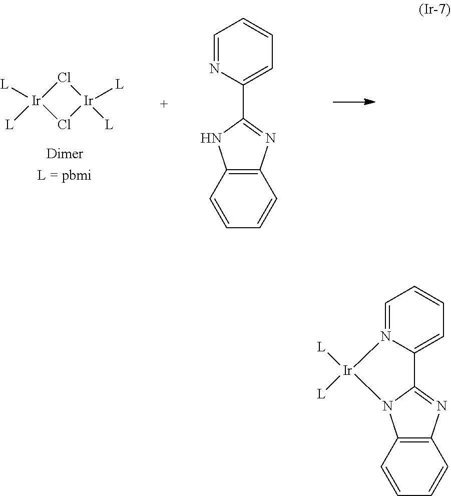

Dimer (26 mg, 0.02 mmol, 1.0 eq), ligand (38 mg, 0.2 mmol, 10.0 eq), Na₂CO₃ (21 mg, 0.2 mmol, 10.0 eq), and ethylene glycol monomethylether (3 mL) were added into a 60 mL sealed tube, and bubbled by N₂ for 5 minutes, then the temperature was raised to 120° C., the mixture was cooled and added with water after reaction for 14 hours, and extracted by dichloromethane (DCM) to separate a liquid, organic phases were dried, and a target point was separated by column chromatography in the case of DCM:MeOH=20:1, thus obtaining a light yellow solid (21 mg in 66% yield).

The emission spectrum in a dichloromethane solution and at room temperature was shown in FIG. 6, wherein a main emission peak was at 534 nm, and the Ir-7 was a green light material.

¹H-NMR (300 MHz, CDCl₃) δ: 9.58 (d, J=8.0 Hz, 1H), 8.16 (d, J=8.1 Hz, 2H), 8.02 (d, J=5.4 Hz, 1H), 7.96 (t, J=7.8 Hz, 1H), 7.92-7.80 (m, 3H), 7.37 (dt, J=16.1, 8.6 Hz, 6H), 7.24 (s, 1H), 7.13 (q, J=7.2, 6.3 Hz, 3H), 6.86 (d, J=7.7 Hz, 1H), 6.81 (d, J=7.1 Hz, 1H), 6.76 (q, J=3.5, 2.6 Hz, 2H), 6.25 (d, 1H), 5.85 (d, J=8.4 Hz, 1H), 3.32 (s, 3H), 3.24 (s, 3H).

ESI MS: 802.2, [M+H]⁺.

### Synthesis Example 9: Ir-9 Synthesis and Structural Characterization

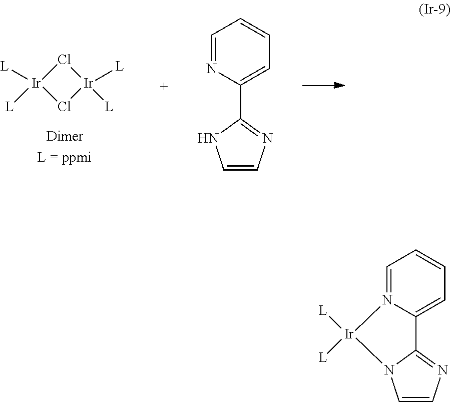

Dimer (26 mg, 0.02 mmol, 1.0 eq), ligand (29 mg, 0.2 mmol, 10.0 eq), Na₂CO₃ (21 mg, 0.2 mmol, 10.0 eq), and ethylene glycol monomethylether (3 mL) were added into a 60 mL sealed tube, and bubbled by N₂ for 5 minutes, then the temperature was raised to 120° C., the mixture was cooled and added with water after reaction for 14 hours, and extracted by dichloromethane (DCM) to separate a liquid, organic phases were dried, and a target point was separated by column chromatography in the case of DCM:MeOH=20:1, thus obtaining a light yellow solid (25 mg in 83% yield).

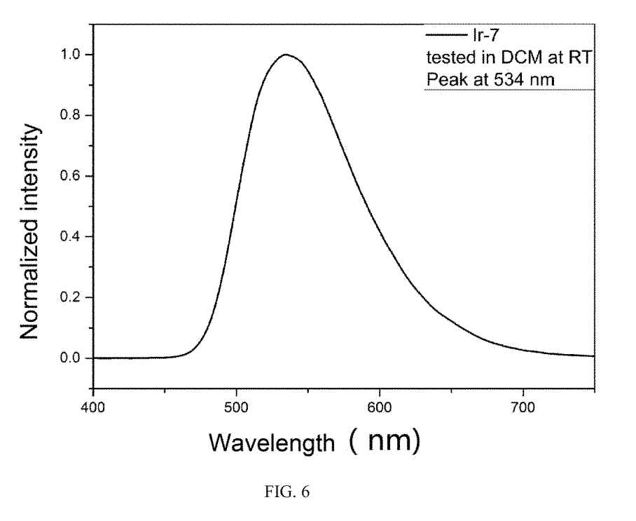

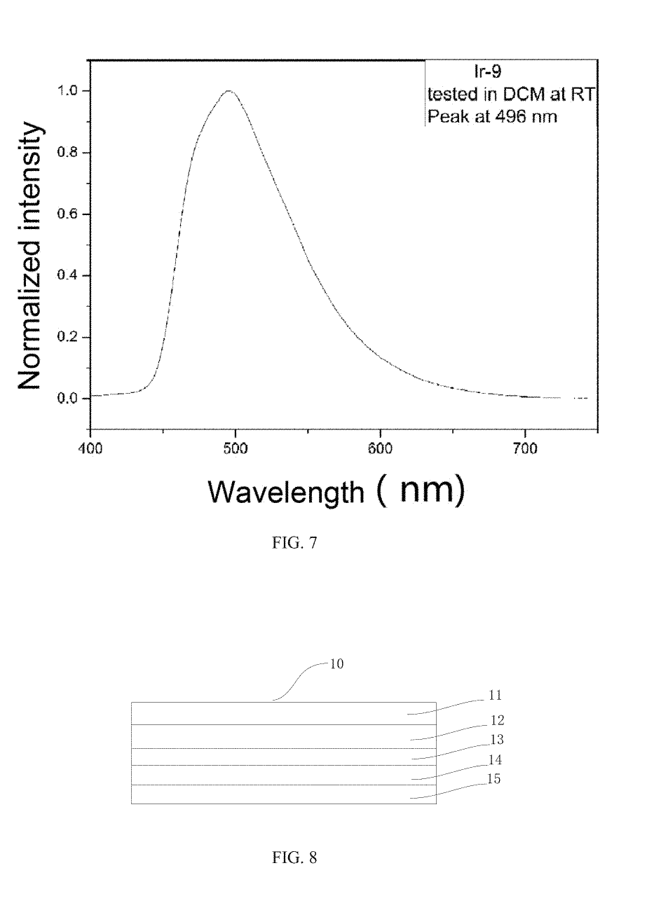

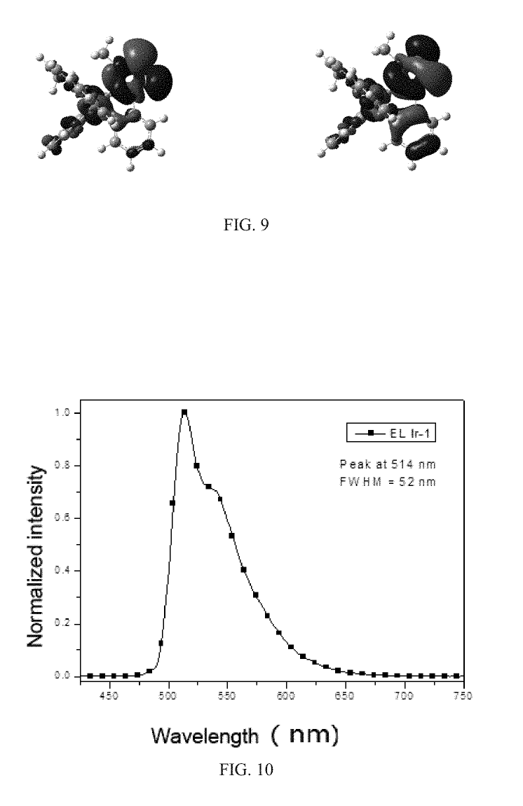

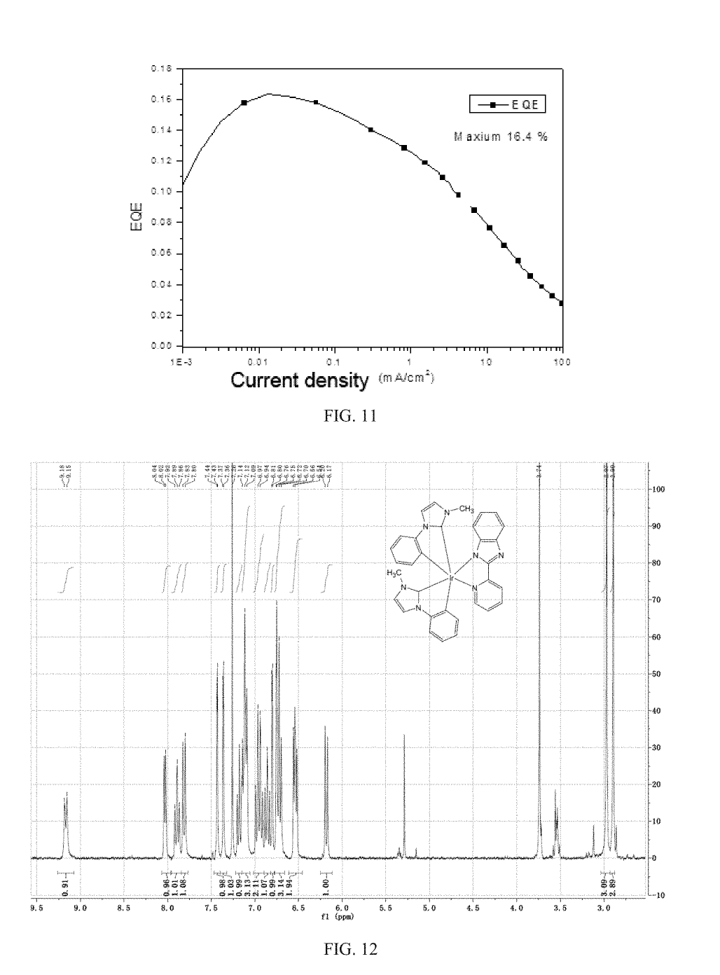

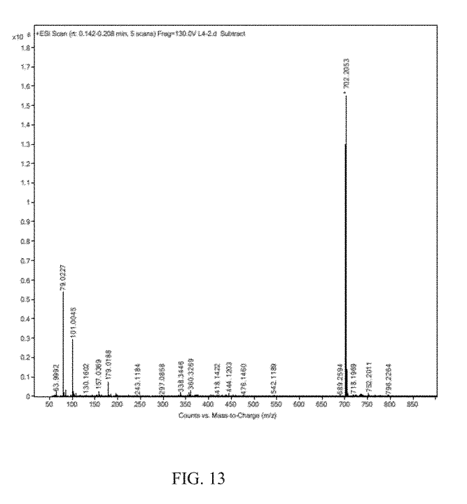

The emission spectrum in a dichloromethane solution and at room temperature was shown in FIG. 7, wherein a main emission peak was at 496 nm, and the Ir-9 was a blue-green light material.

¹H-NMR (300 MHz, CDCl₃) δ: 8.92 (s, 1H), 8.83-8.65 (m, 2H), 8.50 (dd, J=4.9, 1.4 Hz, 2H), 7.97 (d, J=5.5 Hz, 1H), 7.84 (t, J=7.8 Hz, 1H), 7.65 (dd, J=9.8, 7.8 Hz, 2H), 7.36-7.27 (m, 3H), 7.03 (td, J=13.0, 11.4, 5.9 Hz, 3H), 6.70 (dd, J=15.6, 7.8 Hz, 2H), 6.61 (q, J=7.3, 6.1 Hz, 2H), 6.49 (d, J=7.5 Hz, 1H), 3.32 (s, 3H), 3.24 (s, 3H).

ESI MS: 754.2, [M+H]⁺.

wherein, pmi represents

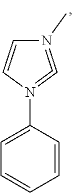

pbmi represents

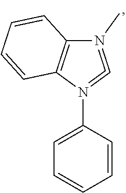

and ppmi represents

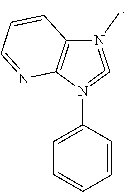

Examples of Photon Efficiency of Complex and Device Performance Test

The quantum efficiencies and the external quantum efficiencies of devices of the iridium complexes Ir-1, Ir-2, Ir-3, Ir-4, Ir-5, Ir-7 and Ir-9 as phosphorescent light emitting materials of the present invention and phosphorescent materials Ir(pmi)₃ and Ir(pbmi)₃ of traditional homoleptic complexes were compared and tested respectively using a method as follows: a photoluminescence quantum efficiency (PLQE) of the material was obtained from the formula

$${Φ}_{s} = {Φ}_{r} ( \frac{{η}_{s}^{2} {A}_{r} {I}_{s}}{{η}_{r}^{2} {A}_{s} {I}_{r}} )$$

based on a relative method (wherein: Φₛ was a fluorescent quantum yield of a sample, Φᵣ was a fluorescent quantum yield of a standard sample, η was a refractive index of a solution, Aₛ and Aᵣ were absorption values at fluorescent excitation wavelengths of the sample and the standard sample respectively, and Iₛ and Iᵣ were fluorescent integral areas of the sample and the standard sample respectively). The material and a target object with known quantum yield were prepared into polymethyl methacrylate (PMMA) of chloroform solutions in the same concentration, and formed a film by spin-coating. Under the same measurement condition, ultraviolet absorption spectrum (GENESYS 10S, Thermo) and fluorescence spectrum (F97pro fluorospectro photometer, Lengguang Technology) were measured. The photon energy (ET1) of the material was calculated according to the formula E=hν=1240/λ (wherein, λ was the wavelength of the tangent at the beginning of the fluorescence spectrum of the PMMA film of the material).

The iridium complex containing an aza-aromatic ancillary ligand described herein is applied to various optical and opto-electronic devices, such as light absorbing devices (including solar and light sensors), light emitting devices, devices having both light absorption and light emission capabilities, and markers for biological applications. The application of the heteroleptic iridium compound containing a nitrogen heterocyclic group described in the present invention to the opto-electronic devices is described below with an organic light emitting diode (OLED) as an example.

FIG. 8 is a sectional view of an OLED10 device. As shown in FIG. 8, the OLED10 device comprises an anode 15 on a substrate, which is made of a transparent material, such as indium tin oxide. The anode 15 may also be a flexible transparent substrate material, such as a conductive polymer film. A hole transporting material layer (HTL) 14 is connected to the anode 15; a light emitting functional layer 13 is located above the hole transporting material layer 14, and the light emitting functional layer 13 comprises light emitting materials of an emitter and a host. An electronic transporting material layer (ETL) 12 and a metal cathode layer 11 are sequentially disposed on the light emitting functional layer 13. The OLED and similar light emitting devices may include one or more layers. In various aspects, any of the one or more layers may include indium tin oxide (ITO), MoO₃, Ni₂O₃, poly(3,4-ethylenedioxythiophene) (PEDOT), Poly (sodium-p-styrenesulfonate) (PSS), 4,4′,4″-((1E,1′E, 1″E)-cyclopropane-1,2,3-trimethylene-tri(cyan-methylylidene))tri(2,3,5,6-tetrafluor obenzonitrile) (NHT-49), 2,2′-(perfluorodecalin-2,6-diyl)malononitrile (NHT-51), 2,3,5,6-tetrafluorotetracyano-p-quinodimethane (F4-TCNQ), N,N′-di-1-naphthyl-N,N′-biphenyl-1,1′-biphenyl-4,4′diamine (NPD), 1,1-bis((di-4-tolylamino)phenyl)cyclohexane (TAPC), 2,6-bis(N-carbazolyl)pyridine (mCpy), 2,8-bis(diphenylphosphoryl)dibenzothiophene (PO15), LiF, LiQ, Cs₂CO₃, CaCO₃, Al, or a combination thereof. In the specific embodiment, the light emitting functional layer 13 may include one or more compounds of the iridium heteroleptic compounds described in the present invention. In the test, an iridium complex 7 is selected, with an optional host material. The ETL layer 12 and the HTL layer 14 may also include one or more iridium heteroleptic compounds and another injection layer close to the electrodes. The material of the injection layer may include (an electron injection layer) EIL, (a hole injection layer) HIL, and a CPL (cap layer), which may be in the form of a single layer or dispersed in a transporting material. The host material may be any known and proper host material in the art. The light emitting color of the OLED is determined by the light emitting energy (optical energy gap) of the light emitting functional layer 13, and the light emitting energy (optical energy gap) of the light emitting functional layer 13 is tuned by tuning the light emitting compound and/or the electronic structure of the host material. The hole transporting material in the HTL layer 14 and the electronic transporting material in the ETL layer 12 may include any known and proper hole transporting body in the art.

The quantum efficiencies and the external quantum efficiencies of devices of the iridium complexes Ir-1, Ir-2, Ir-3, Ir-4, Ir-5, Ir-7 and Ir-9 as phosphorescent light emitting materials and phosphorescent materials Ir(pmi)₃ and Ir(pbmi)₃ of traditional homoleptic complexes were compared and tested respectively using a method as follows, wherein the structure of the OLED device was designed as follows: ITO/HATCN (10 nm)/TAPC (40 nm)/mCP: dopant (20 nm, 6%)/TmPyPB (40 nm)/LiF (10 nm)/Al.

The photon efficiency and device results were shown in Table 1 as below:

TABLE 1

| | PLQE | Peak | CE at | |
|---|---|---|---|---|
| Complex | in PMMA | (nm) | 1000 cd²A⁻¹ | PE lmW⁻¹ at 1000 cd²A⁻¹ |
| Ir(pmi)₃ | <5% | —^{a} | —^{a} | —^{a} |
| Ir(pbmi)₃ | 39% | —^{b} | —^{b} | —^{b} |
| Ir-1 | 67% | 514 | 10.6 | 9.1 |
| Ir-2 | 59% | 563 | 5.8 | 4.1 |
| Ir-3 | 75% | 506 | 17.8 | 19.3 |
| Ir-4 | 94% | 507 | 16.2 | 15.7 |
| Ir-5 | 49% | 551 | 9.3 | 7.9 |
| Ir-7 | 71% | 545 | 12.7 | 15.7 |
| Ir-9 | 84% | 508 | 15.2 | 18.9 |

In the device preparation, a was not stable and was easily decomposed. The energy level of b was too high to match the device.

As shown in Table 1, through comparing the device data, the electroluminescence wavelength of the device is mainly determined by the photoluminescence of the Ir complex itself, and the wavelength has slight red shift with respect to the fluorescent emission wavelength in the PMMA. Compared with the homoleptic Ir complex of the main ligand, the energy level has a large red shift from a blue light region to a blue-green and green light region. Under the same condition, the efficiency of the device is also basically consistent with the PLQE trend of the Ir complex itself, which indicates that the device structure reflects the property of the compound itself. Therefore, the high PLQE iridium compound disclosed in the present invention can obtain higher device efficiency than the existing device in other devices, which proves that the design of these materials can improve the stability of the device in the light emitting process and achieve high light emitting efficiency. Therefore, the iridium compound can be used as a core organic light emitting unit in the OLED.

Those of ordinary skill in the art can understand that the above embodiments are specific embodiments for implementing the invention, and in practical applications, various changes in form and detail can be made without departing from the spirit and scope of the invention.

What is claimed is:

1. An organic metal complex, comprising a structure as shown in a general formula (I): 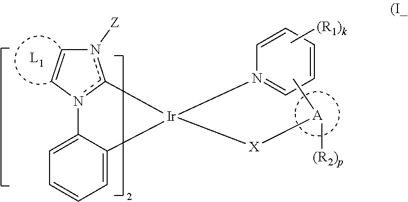
wherein,
each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to an adjacent aryl or substituent optionally;
a structure A is selected from substituted or unsubstituted C₁-C₆ alkylene, substituted or unsubstituted C₃-C₃₆ heteroaromatic ring, and substituted or unsubstituted C₆-C₃₆ aromatic ring; and the structure A is connected to a pyridine ring;
X represents a carbon atom, an oxygen atom or a nitrogen atom; and X is connected to the structure A or X is an atom in the structure A;
each of k and p is independently an integer of 1 to 4;
Z is a halogen, C₁-C₆ alkyl, or C₁-C₆ deuterated alkyl; and
L₁ is selected from substituted or unsubstituted C₃-C₃₆ heteroaromatic ring, and substituted or unsubstituted C₆-C₃₆ aromatic ring; and L₁ is condensed with an imidazole ring.

2. The organic metal complex according to claim 1, wherein,
when X represents the carbon atom, the structure A is selected from substituted or unsubstituted C₃-C₃₆ heteroaromatic ring, and substituted or unsubstituted C₆-C₃₆ aromatic ring, and X is the atom in the structure A;
when X represents the nitrogen atom, the structure A is selected from substituted or unsubstituted C₃-C₃₆ heteroaromatic ring, and X is the atom in the structure A; and
when X represents the oxygen atom, the structure A is selected from substituted or unsubstituted C₁-C₆ alkylene, substituted or unsubstituted C₃-C₃₆ heteroaromatic ring, and substituted or unsubstituted C₆-C₃₆ aromatic ring, and X is connected to the structure A.

3. The organic metal complex according to claim 1, comprising a structure as shown in a general formula (IA): 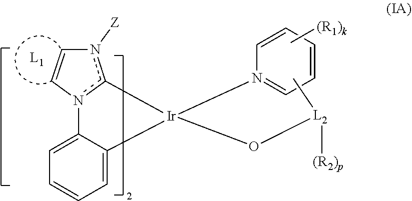
wherein,
each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to the adjacent aryl or substituent optionally;
each of k and p is independently an integer of 1 to 4;
L₂ is selected from substituted or unsubstituted C₁-C₆ alkylene, substituted or unsubstituted C₃-C₃₆ heteroaromatic ring, and substituted or unsubstituted C₆-C₃₆ aromatic ring; and L₂ is connected to the pyridine ring; and
Z is a halogen, C₁-C₆ alkyl, or C₁-C₆ deuterated alkyl.

4. The organic metal complex according to claim 1, comprising a structure as shown in a general formula (IB): 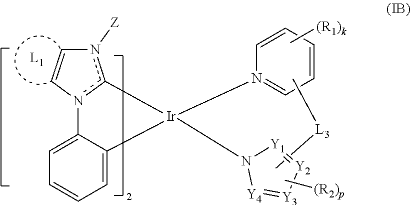
wherein,
each of R₁ and R₂ is independently selected from hydrogen, deuterium, substituted or unsubstituted C₁-C₆ alkyl, substituted or unsubstituted C₁-C₆ deuterated alkyl, substituted or unsubstituted C₃-C₃₆ heteroaryl, substituted or unsubstituted C₆-C₃₆ aryl, substituted or unsubstituted C₃-C₃₆ deuterated heteroaryl, and substituted or unsubstituted C₆-C₃₆ deuterated aryl; and each of R₁ and R₂ is independently connected to the adjacent aryl or substituent optionally;
each of k and p is independently an integer of 1 to 4;
each of Y₁, Y₂, Y₃ and Y₄ is independently selected from the nitrogen atom and the carbon atom;
L₃ is selected from a dummy atom, substituted or unsubstituted C₁-C₆ alkylene, substituted or unsubstituted C₃-C₃₆ heteroaromatic ring, and substituted or unsubstituted C₆-C₃₆ aromatic ring;
L₃ is connected to or condensed with the pyridine ring, and L₃ is connected to or condensed with a five-membered ring formed by Y₁, Y₂, Y₃, Y₄ and an N atom; and
Z is a halogen, C₁-C₆ alkyl, or C₁-C₆ deuterated alkyl.

5. The organic metal complex according to claim 1, wherein in the general formula structure of the organic metal complex, a right ligand 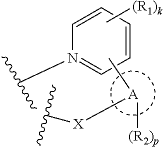
is selected from one of the following structures: 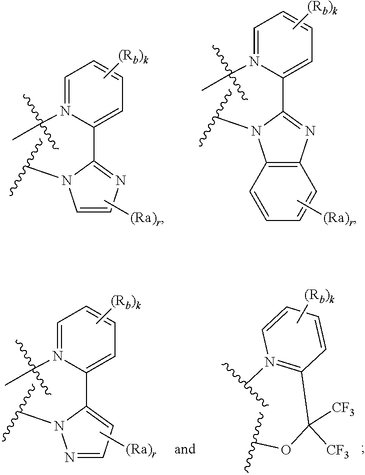
wherein,
each of Ra and Rb is independently selected from hydrogen, deuterium, substituted or unsubstituted C₁-C₆ alkyl, substituted or unsubstituted C₁-C₆ deuterated alkyl, substituted or unsubstituted C₆-C₃₆ aryl, and substituted or unsubstituted C₆-C₃₆ deuterated aryl, and each of Ra and Rb is independently connected to the adjacent aryl or substituent optionally; and
each of r and k is independently an integer of 1 to 4.

6. The organic metal complex according to claim 5, wherein in the general formula structure of the organic metal complex, the right ligand 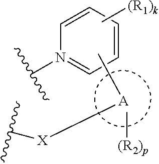
is selected from one of the following structures:

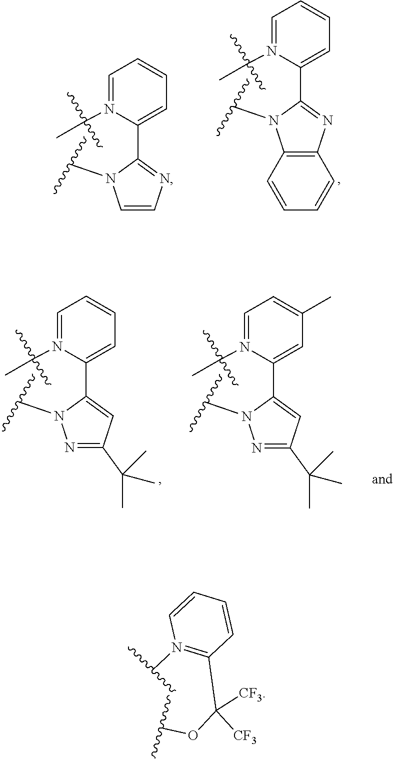

7. The organic metal complex according to claim 1, wherein in the general formula structure of the organic metal complex, a left ligand 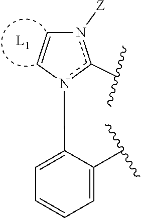
is selected from one of the following structures:

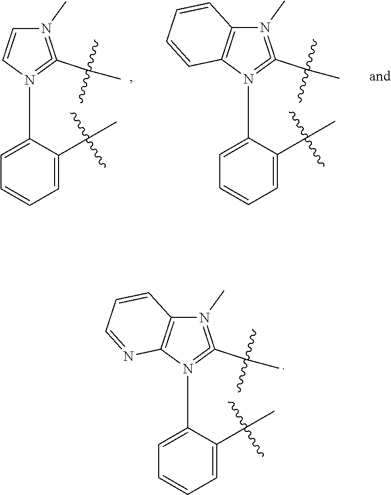

8. The organic metal complex according to claim 1, wherein the organic metal complex has one of the following structures as below:

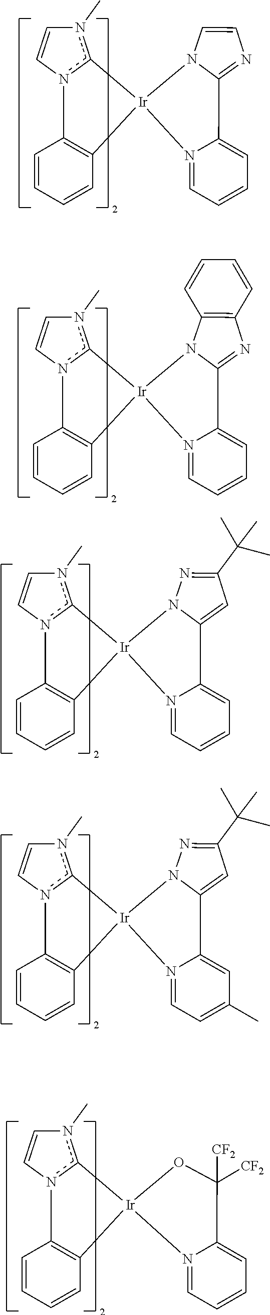

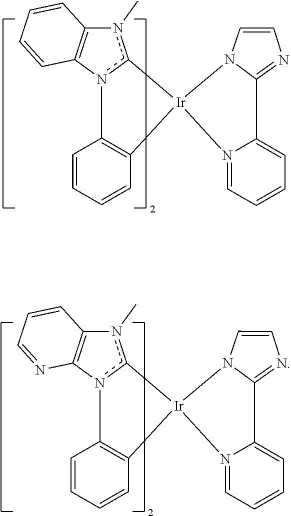

9. A preparation method of the organic metal complex according to claim 1, comprising the following steps:
(1) obtaining a dimer by a precursor substance reacting with iridium chloride; and
(2) obtaining a compound as shown in the general formula (I) by the dimer reacting with a ligand compound;

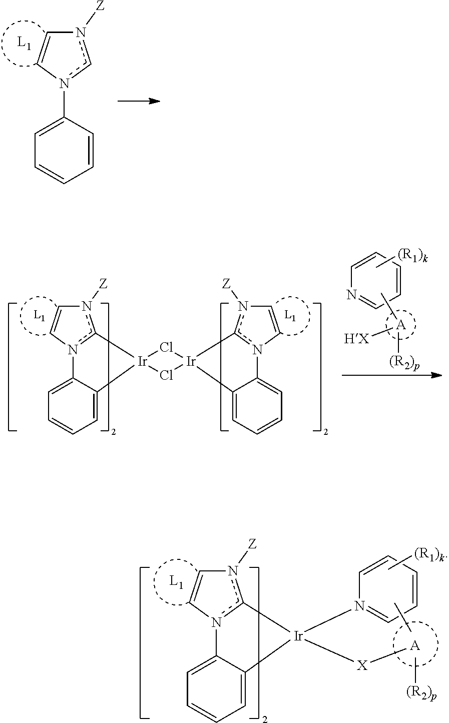

10. An organic electronic component, comprising the organic metal complex according to claim 1.

11. The electronic component according to claim 10, wherein the electronic component is an organic light emitting diode, a compact fluorescent lamp, an organic photovoltaic cell, an organic field effect transistor or a light emitting electrochemical cell.
